(19) United States
(12) Patent Application Publication
(10) Pub. No.: US 2025/0267846 A1
(43) Pub. Date: Aug. 21, 2025

(54) SEMICONDUCTOR MEMORY DEVICE AND METHOD OF FABRICATING THE SAME

(71) Applicant: Samsung Electronics Co., Ltd., Suwon-si (KR)

(72) Inventors: Jihyun HWANG, Suwon-si (KR); Byunghoon KIM, Suwon-si (KR); Yongseok SUH, Suwon-si (KR); BOK-YEON WON, Suwon-si (KR); Yongseok LEE, Suwon-si (KR); Hogyu CHOI, Suwon-si (KR)

(21) Appl. No.: 18/930,044

(22) Filed: Oct. 29, 2024

(30) Foreign Application Priority Data
Feb. 21, 2024 (KR) 10-2024-0025142

(51) Int. Cl. H10B 12/00

(52) U.S. Cl. CPC H10B 12/315; H10B 12/482; H10B 12/488; H10B 12/50

(57) ABSTRACT

Provided are a semiconductor memory device and a method of fabricating the same. This semiconductor memory device includes a substrate including a memory region, a dummy region, and a peripheral region arranged side by side in a first direction, and a device isolation part arranged in the substrate in the memory region and the dummy region and defining active parts, wherein the active parts include first to third active parts arranged side by side in a second direction perpendicular to the first direction in the dummy region, the first to third active parts are each elongated in a third direction intersecting the first direction and the second direction, and ends of at least two of the first to third active parts are located on a first imaginary straight line extending in the second direction.

### CROSS-REFERENCE TO RELATED APPLICATIONS

This U.S. non-provisional patent application claims priority under 35 U.S.C. § 119 of Korean Patent Application No. 10-2024-0025142, filed on Feb. 21, 2024, the entire contents of which is hereby incorporated by reference.

### BACKGROUND

The present disclosure herein relates to a semiconductor memory device and a method of fabricating the same.

In the electronic industry, semiconductor memory devices are regarded as important elements due to characteristics thereof such as a small size, multiple functions, and/or low manufacturing cost. However, with the development of the electronic industry, semiconductor memory devices have become more highly integrated. In order to highly integrate semiconductor memory devices, the line widths of patterns in semiconductor memory devices are being reduced gradually. However, since recent fine patterning requires new exposure technology, high-cost exposure technology, and/or the like, it is increasingly difficult to highly integrate semiconductor memory devices. Accordingly, recently, researches are being actively conducted to develop new integration technology.

### SUMMARY

The present disclosure provides a semiconductor memory device with improved reliability.

The present disclosure also provides a method of fabricating a semiconductor memory device capable of improving a yield.

An embodiment of the inventive concept provides a semiconductor memory device including: a substrate including a memory region, a dummy region, and a peripheral region arranged side by side in a first direction; and a device isolation part arranged in the substrate in the memory region and the dummy region and defining active parts, wherein the active parts include first to third active parts arranged side by side in a second direction perpendicular to the first direction in the dummy region, the first to third active parts are each elongated in a third direction intersecting the first direction and the second direction, and ends of at least two of the first to third active parts are located on a first imaginary straight line extending in the second direction.

In an embodiment of the inventive concept, a semiconductor memory device includes: a substrate including a memory region, a dummy region, and a peripheral region arranged side by side in a first direction; and a device isolation part arranged in the substrate in the memory region and the dummy region and defining active parts, wherein the active parts include first to third active parts arranged in the dummy region and fourth active parts arranged in the memory region, the first to third active parts are arranged side by side in a second direction perpendicular to the first direction, the first to fourth active parts are elongated in a third direction intersecting the first direction and the second direction, one of the first to third active parts has a first length in the third direction, and each of the fourth active parts has a second length smaller than the first length in the third direction.

In an embodiment of the inventive concept, a semiconductor memory device includes: a substrate including a cell array region and a peripheral region arranged side by side in a first direction; a device isolation part arranged in the substrate in the cell array region and defining active parts, wherein the active parts are arranged two-dimensionally in the first direction and a second direction perpendicular to the first direction, and each of the active parts is elongated in a third direction intersecting the first direction and the second direction; word lines arranged in the substrate, extending lengthwise in the second direction, and traversing the active parts in the cell array region; first impurity regions arranged in the active parts and adjacent to first sidewalls of the word lines; second impurity regions arranged in the active parts and adjacent to second sidewalls of the word lines; bit lines respectively connected to the first impurity regions, arranged on the substrate, and extending in the first direction; and storage node contacts respectively connected to the second impurity regions, wherein ends of at least two among active parts that are closest to the peripheral region are located on a first imaginary straight line extending in the second direction.

In an embodiment of the inventive concept, a method of fabricating a semiconductor memory device includes: providing an etching target layer including a cell array region, a boundary region, and a peripheral region arranged side by side in a first direction; sequentially stacking first and second mask layers on the etching target layer; forming third line patterns and a third peripheral pattern on the second mask layer, wherein the third peripheral pattern extends in a second direction intersecting the first direction and covers the peripheral region, the third line patterns traverse the cell array region in a third direction intersecting the first direction and the second direction, and an end of the third peripheral pattern is located in the boundary region; forming first cell spacer patterns covering sidewalls of the third line patterns and a first peripheral spacer pattern covering a sidewall of the third peripheral pattern; forming a buried pattern filling a space between the first cell spacer patterns and the first peripheral spacers in the boundary region; removing the third line patterns in the cell array region; forming second line patterns by patterning the second mask layer using the first cell spacer patterns as an etching mask in the cell array region and forming a second peripheral pattern by patterning the second mask layer using the first cell spacer patterns, the first peripheral spacer patterns, the buried pattern, and the third peripheral pattern as an etching mask in the boundary region and the peripheral region; forming second cell spacer patterns covering sidewalls of the second line patterns and forming second peripheral spacer patterns covering a sidewall of the second peripheral pattern; removing the second line patterns; and forming first line patterns by patterning the first mask layer using the second cell spacer patterns as an etching mask and forming a first peripheral pattern by patterning the first mask layer using the second peripheral pattern and the second peripheral spacer patterns as an etching mask.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view of a semiconductor memory device according to example embodiments of the inventive concept;

FIGS. 2A to 2C are enlarged views of portion P1 of FIG. 1 according to example embodiments of the inventive concept;

FIG. 3 is a cross-sectional view taken along line A1-A2 of FIG. 2A according to example embodiments of the inventive concept;

FIG. 4A is an enlarged plan view of portion P2 of FIG. 2A according to example embodiments of the inventive concept;

FIG. 4B is a cross-sectional view taken along lines B1-B2 and C1-C2 of FIG. 4A according to example embodiments of the inventive concept;

FIGS. 5A to 21A are plan views sequentially illustrating an example process of fabricating a semiconductor memory device having the plane of FIG. 2A; and

FIGS. 5B to 21B are cross-sectional views sequentially illustrating an example process of fabricating a semiconductor memory device having the cross-section of FIG. 3.

### DETAILED DESCRIPTION

Hereinafter, embodiments according to the inventive concept will be described in more detail with reference to the accompanying drawings in order to more specifically describe the inventive concept. Herein, the terms indicating order, such as first, and second, are used to distinguish elements having the same/similar functions, and the ordinal numbers may be interchanged according to the order in which the elements are mentioned.

Like reference characters refer to like elements throughout. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

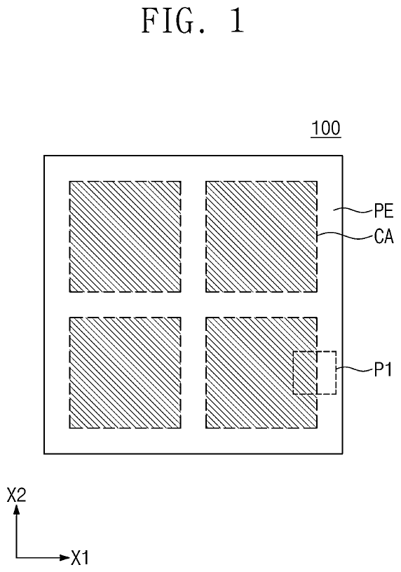

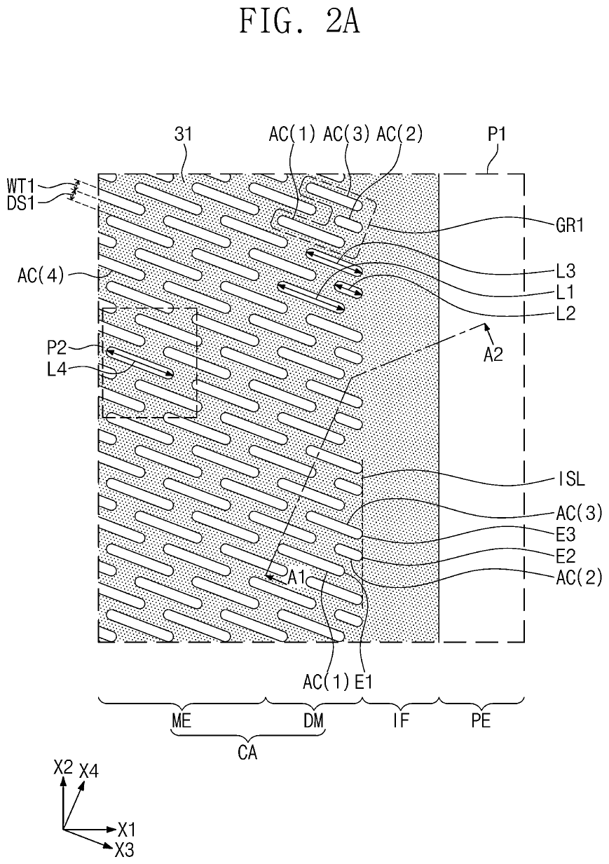

FIG. 1 is a plan view of a semiconductor memory device according to example embodiments of the inventive concept.

Referring to FIG. 1, a semiconductor memory device 100 according to the inventive concept may include a plurality of cell array regions CA arranged two-dimensionally along a first direction X1 and a second direction X2 perpendicular to each other. The number and arrangement of the cell array regions CA may be varied without being limited to FIG. 1. A peripheral region PE may be arranged between the cell array regions CA. The peripheral region PE may surround each of the cell array regions CA. A plurality of memory cells may be arranged in the cell array region CA. The memory cells each may be connected to a word line and a bit line intersecting each other. A core circuit unit or peripheral circuit unit may be arranged in the peripheral region PE. The core circuit unit may include a sub-word line driver and a sense amplifier. The peripheral circuit unit may include a row decoder, a column decoder, a control logic circuit, etc.

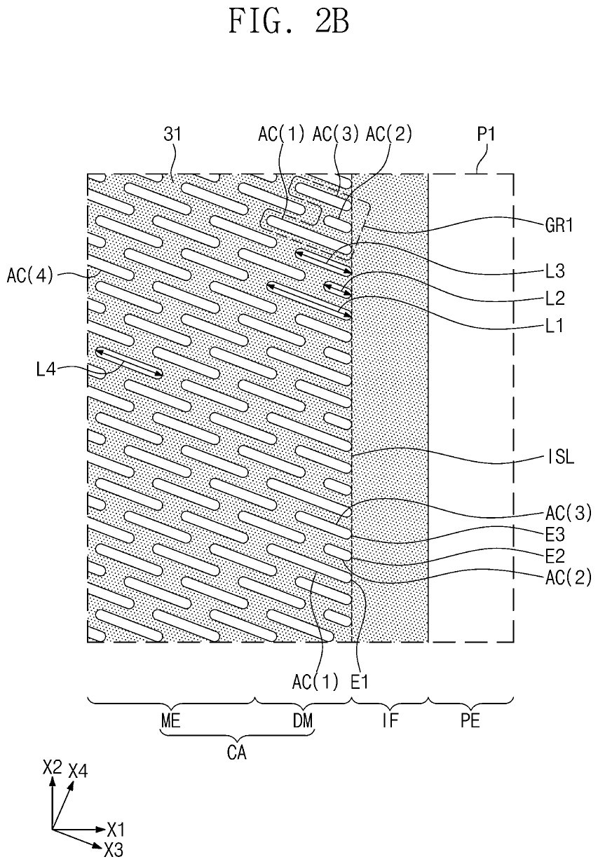

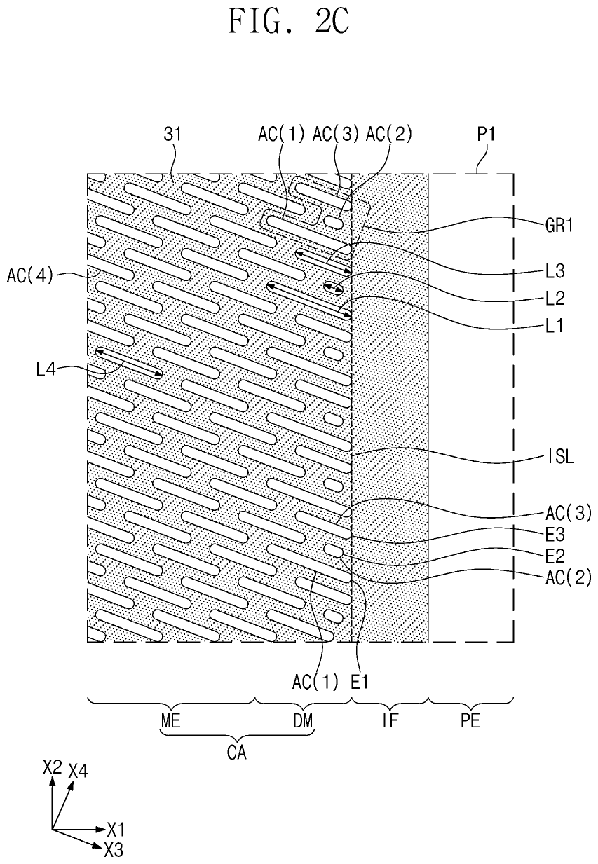

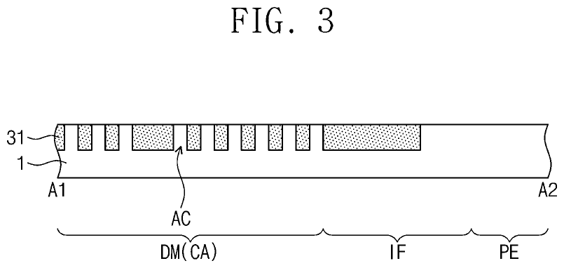

FIGS. 2A to 2C are enlarged views of portion P1 of FIG. 1 according to example embodiments of the inventive concept. FIG. 3 is a cross-sectional view taken along line A1-A2 of FIG. 2A according to example embodiments of the inventive concept.

Referring to FIGS. 2A to 2C and 3, a substrate 1 may include the cell array region CA, a boundary region IF, and the peripheral region PE that are arranged side by side along the first direction X1. The substrate 1 may include a semiconductor material. The boundary region IF may be arranged between the cell array region CA and the peripheral region PE. The boundary region IF may completely surround each of the cell array regions CA. The boundary region IF may also be referred to as an extension region. The cell array region CA may include a memory region ME and a dummy region DM. The dummy region DM may be arranged between the boundary region IF and the memory region ME of the cell array region CA. Memory cells actually functioning as a memory may be arranged in the memory region ME. Dummy memory cells not functioning as a memory may be arranged in the dummy region DM. The dummy region DM may be present to prevent a process fault due to a loading effect during a fabrication process of a semiconductor memory device. As used herein, the term “dummy” is used to refer to a component that has substantially the same structure and shape as other components but does not have a substantial function and exists only as a pattern in the device. For example, a dummy memory cells arranged in the dummy region DM may have substantially the same structure and shape as the functioning memory cells arranged in the memory region ME.

A device isolation part 31 may be arranged in the substrate 1 to define active parts AC in the cell array region CA. The device isolation part 31 may have a single-layer or multi-layer structure of at least one of silicon oxide, silicon nitride, or silicon oxynitride. The active parts AC may include first to third active parts AC(1) to AC(3) arranged in the dummy region DM and fourth active parts AC(4) arranged in the memory region ME. The active parts AC may be two-dimensionally arranged along the first direction X1 and the second direction X2 perpendicular to the first direction X1. The active parts AC may each have a bar shape elongated in a third direction X3 intersecting the first direction X1 and the second direction X2. Each of the first direction X1, the second direction X2, the third direction X3, and a fourth direction X4 may be horizontal directions, which are parallel to an upper surface of the substrate 1.

The first to third active parts AC(1) to AC(3) arranged in the dummy region DM may be arranged side by side along the second direction X2 perpendicular to the first direction X1. For example, the first to third active parts AC(1) to AC(3) arranged in the dummy region DM may extend lengthwise in parallel to one another. The first to third active parts AC(1) to AC(3) may form one group GR1 and may be repeatedly arranged along the second direction X2.

In an embodiment of the inventive concept, ends of at least two of the first to third active parts AC(1) to AC(3) may be arranged on a first imaginary straight line ISL extending along the second direction X2. The first imaginary straight line ISL may extend along the second direction X2 at an interface of the cell array region CA and the boundary region IF.

In more detail, in FIG. 2A, ends E2 and E3 of the second and third active parts AC(2) and AC(3) may be arranged on the first imaginary straight line ISL, and an end E1 of the first active part AC(1) may be spaced apart from the first imaginary straight line ISL. Alternatively, referring to FIG. 2B, all of the ends E1 to E3 of the first to third active parts AC(1) to AC(3) may be arranged on the first imaginary straight line ISL. Alternatively, referring to FIG. 2C, the ends E1 and E3 of the first and third active parts AC(1) and AC(3) may be arranged on the first imaginary straight line ISL, and the end E2 of the second active part AC(2) may be spaced apart from the first imaginary straight line ISL.

The first active part AC(1) may have a first length L1 in the third direction X3. The second active part AC(2) may have a second length L2 different from the first length L1 in the third direction X3. The third active part AC(3) may have a third length L3 different from the first length L1 and second length L2 in the third direction X3. In FIGS. 2A to 2C, the third length L3 is larger than the second length L2 and smaller than the first length L1.

The fourth active parts AC(4) may have a fourth length L4 in the third direction X3. The fourth length L4 may be different from the first length L1 and the second length L2. The fourth length L4 may be equal to the first length L1 as illustrated in FIG. 2A. Alternatively, the fourth length L4 may be less than the first length L1 as illustrated in FIGS. 2B and 2C.

The active parts AC may be spaced apart from each other in a fourth direction X4 intersecting the first direction X1 and second direction X2 and perpendicular to the third direction X3. Here, the active parts AC may be spaced apart a first distance DS1 apart from each other in the fourth direction X4. The active parts AC may have a first width WT1 in the fourth direction X4. The first width WT1 may be equal to the first distance DS1.

The device isolation part 31 may extend from the cell array region CA to the boundary region IF and define the peripheral region PE. For example, the sidewall of the device isolation part 31 may be aligned with the interface with the peripheral region PE. The device isolation part 31 may have a line shape extending in the second direction X2 in the boundary region IF.

Since no faulty pattern remains in the boundary region IF in the semiconductor memory device according to the present example, reliability of the device may be improved. Furthermore, ends of the active parts AC are arranged on the imaginary straight line ISL at an edge of the cell array region CA and do not protrude to the boundary region IF. Accordingly, the cell array region CA may not increase in size, and a distance between the cell array region CA and the peripheral region PE may be maintained as a predetermined distance. Therefore, the degree of integration may be increased. Furthermore, since signal interference between memory cells in the cell array region CA and peripheral circuits in the peripheral region PE may be prevented, the reliability may be improved.

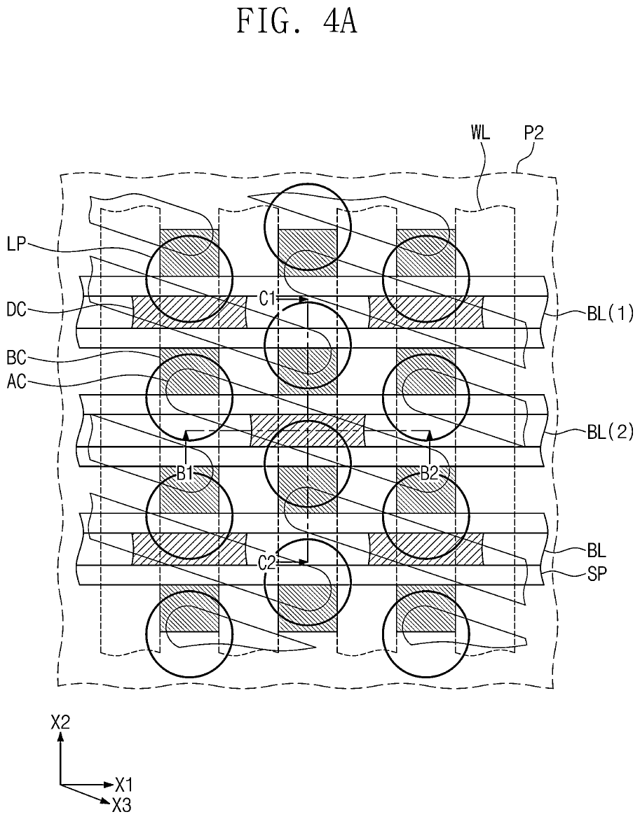

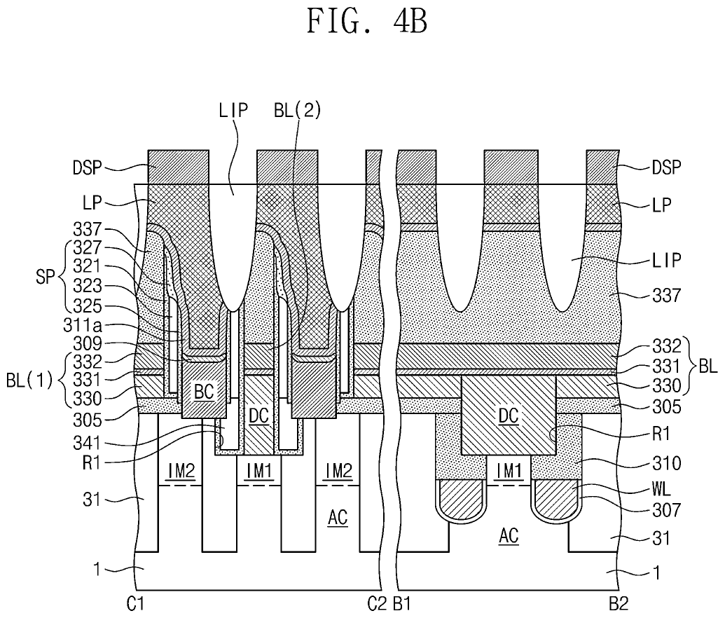

FIG. 4A is an enlarged plan view of portion P2 of FIG. 2A according to embodiments of the inventive concept. FIG. 4B is a cross-sectional view taken along lines B1-B2 and C1-C2 of FIG. 4A according to embodiments of the inventive concept.

Referring to FIGS. 4A and 4B, the device isolation part 31 may be arranged in the substrate 1 to define the active parts AC. The active parts AC may each have an isolated shape. The active parts AC each may have a bar shape elongated in the third direction X3 in a plan view. In a plan view, the active parts AC may respectively correspond to portions of the substrate 1 surrounded by the device isolation part 31. The substrate 1 may include a semiconductor material. An end of one active part AC may be arranged adjacent to a center of another active part AC adjacent to the one active part AC.

Word lines WL may traverse the active parts AC. The word lines WL may be arranged in grooves formed in the active parts AC and the device isolation part 31. The word lines WL may be parallel to the second direction X2 intersecting the third direction X3. The word lines WL may be formed of a conductive material. A gate dielectric layer 307 may be arranged between each of the word lines WL and an inner surface of each of the grooves. Upper surfaces of the gate dielectric layer 307 and the word lines WL may be coplanar. Although not illustrated, a bottom of the grooves may be relatively deep within the device isolation part 31 and relatively shallow within the active parts AC. The gate dielectric layer 307 may include at least one of thermal oxide, silicon nitride, silicon oxynitride, or a high-k dielectric material. A lower surface of the word lines WL may be curved.

A first impurity region IM1 may be arranged within each of the active parts AC between a pair of the word lines WL, and a pair of second impurity regions IM2 may be respectively arranged within two edge regions of each of the active parts AC. The first impurity region IM1 and the second impurity region IM2 may be doped with, for example, N-type impurities. Each of the word lines WL and the first and second impurity regions IM1 and IM2 adjacent thereto may constitute a transistor. Since the word lines WL are arranged within the grooves, a channel length of a channel region under the word lines WL may be increased within a limited plane area. Therefore, a short channel effect or the like may be minimized.

An upper surface of the word lines WL may be lower than an upper surface of the active parts AC. A word line capping pattern 310 may be arranged on each of the word lines WL. The word line capping patterns 310 may have a line shape extending in a longitudinal direction of the word lines WL and may entirely cover upper surfaces of the word lines WL. The word line capping patterns 310 may fill the grooves above the word lines WL. The word line capping patterns 310 may contact upper surfaces of the word lines WL and the gate dielectric layer 307. Upper surfaces of the word line capping patterns 310 may be coplanar with an upper surface of the device isolation part 31. The word line capping pattern 310 may be formed of, for example, a silicon nitride layer.

An interlayer insulating pattern 305 may be arranged on the substrate 1. The interlayer insulating pattern 305 may be formed of at least one single-layer or multi-layer selected among a silicon oxide layer, a silicon nitride layer, and a silicon oxynitride layer. The interlayer insulating pattern 305 may be formed in a shape of islands spaced apart from each other in a plan view. The interlayer insulating pattern 305 may be formed so as to simultaneously cover ends of two adjacent active parts AC.

Upper portions of the substrate 1, the device isolation part 31, and the word line capping pattern 310 may be partially recessed, thus forming a first recess region R1. The first recess region R1 may form a mesh shape in a plan view. A sidewall of the first recess region R1 may be aligned with a sidewall of the interlayer insulating pattern 305.

Bit lines BL may be arranged on the interlayer insulating pattern 305. The bit lines BL may traverse the word line capping patterns 310 and the word lines WL. As illustrated in FIG. 4A, the bit lines BL may be parallel to the first direction X1 intersecting the third and second directions X3 and X2. The bit lines BL may include a bit line polysilicon pattern 330, a first metal pattern 331, and a second metal pattern 332 that are sequentially stacked. For example, the second metal pattern 332 may contact an upper surface of the first metal pattern 331, the first metal pattern 331 may contact an upper surface of the bit line polysilicon pattern 330, and the bit line polysilicon pattern 330 may contact an upper surface of the interlayer insulating pattern 305. The bit line polysilicon pattern 330 may include polysilicon doped with impurities. The first metal pattern 331 may include a single-layer or multi-layer structure of at least one of titanium, titanium nitride, tantalum, tantalum nitride, tungsten nitride, cobalt silicide, or titanium silicide. The second metal pattern 332 may include metal (e.g., tungsten, titanium, tantalum, etc.). A bit line capping pattern 337 may be arranged on each of the bit lines BL. The bit line capping pattern 337 may contact an upper surface of the second metal pattern 332. The bit line capping patterns 337 may be formed of an insulating material such as a silicon nitride layer.

Bit line contacts DC may be arranged in the first recess region R1 intersecting the bit lines BL. The bit line contacts DC may include polysilicon doped with impurities. In the cross-sectional view taken along line B1-B2 of FIG. 4B, one sidewall of the bit line contact DC may be in contact with a side surface of the interlayer insulating pattern 305. In addition, the bit line contact DC may contact the bit line polysilicon pattern 330 and the word line capping pattern 310. In the plan view of FIG. 4A, one side surface of the bit line contact DC may be concave. The bit line contact DC may electrically connect the first impurity region IM1 to the bit line BL.

A lower buried insulating pattern 341 may be arranged in the first recess region R1 in which the bit line contact DC is not arranged. The lower buried insulating pattern 341 may be formed of at least one single-layer or multi-layer selected from the group consisting of a silicon oxide layer, a silicon nitride layer, and a silicon oxynitride layer.

Storage node contacts BC may be arranged between a pair of adjacent bit lines BL(1) and BL(2). The storage node contacts BC may be spaced apart from each other. The storage node contacts BC may include polysilicon doped or undoped with impurities. Upper surfaces of the storage node contacts BC may be concave. An insulating pattern (not shown) may be arranged between the storage node contacts BC between the bit lines BL.

A spacer structure SP may be interposed between the bit line BL and the storage node contact BC. The spacer structure SP may extend in the first direction X1 along a side surface of the bit line BL in the plan view of FIG. 4A.

The spacer structure SP may include first to fourth spacers 321, 323, 325, and 327. The first spacer 321 covers side surfaces of the bit line BL and the bit line capping pattern 337. The first spacer 321 may extend and cover an inner sidewall and a bottom surface of the first recess region R1. The second spacer 323 may cover a lower sidewall but expose an upper sidewall of the first spacer 321. The first spacer 321 may extend and cover a lower surface of the second spacer 323. The third spacer 325 may cover a side surface of the second spacer 323. One lower end of the first spacer 321 may be in contact with the third spacer 325. The fourth spacer 327 may cover an upper sidewall of the first spacer 321 and cover an upper surface of the second spacer 323. The second spacer 323 may include a material different from materials of the first spacer 321, the third spacer 325, and the fourth spacer 327. For example, the first spacer 321, the third spacer 325, and the fourth spacer 327 may be formed of silicon nitride. The second spacer 323 may be formed of silicon oxide. Alternatively, the second spacer 323 may be an air gap region. For example, an air gap region may be a region comprised of air. The term “air” as discussed herein, may refer to atmospheric air or other gases that may be present during the manufacturing process. An upper width of the spacer structure SP is less than a lower width thereof. Therefore, a margin for forming a subsequent landing pad LP may increase. Accordingly, the landing pad LP and the storage node contact BC may be prevented from being disconnected from each other.

Although not illustrated, node isolation patterns may be respectively arranged between the storage node contacts BC spaced apart from each other in the third direction X3 between the adjacent bit lines BL(1) and BL(2).

Referring to FIG. 4B, a storage node ohmic layer 309 is arranged on the storage node contact BC. The storage node ohmic layer 309 may include metal silicide. An upper surface of the storage node ohmic layer 309, the spacer structure SP, and the bit line capping pattern 337 may be conformally covered with a diffusion prevention pattern 311a. The diffusion prevention pattern 311a may contact upper surfaces of the bit line capping pattern 337. The diffusion prevention pattern 311a may include a single-layer or multi-layer structure of at least one of titanium, titanium nitride, tantalum, tantalum nitride, or tungsten nitride.

Referring to FIG. 4B, the landing pad LP is arranged on the diffusion prevention pattern 311a. The landing pad LP may be formed of a material containing metal such as tungsten. An upper center of the landing pad LP may be shifted from a center of the storage node contact BC in the second direction X2. A portion of the bit line BL may vertically overlap the landing pad LP.

A landing pad isolation pattern LIP may be arranged between the landing pads LP to isolate the landing pads LP from each other. A portion of the landing pad isolation pattern LIP may penetrate a portion of the bit line capping pattern 337. A portion of the landing pad isolation pattern LIP may penetrate the fourth spacer 327 adjacent to the bit line contact DC and be in contact with an upper portion of the second spacer 323. The landing pad isolation pattern LIP may include a single-layer or multi-layer structure of at least one of a silicon nitride layer, a silicon oxide layer, a silicon oxynitride layer, or a porous layer.

A data storage pattern DSP may be arranged on the landing pads LP. The data storage pattern DSP may be a capacitor including a lower electrode, a dielectric layer, and an upper electrode. In this case, the semiconductor memory device may be a dynamic random-access memory (DRAM). Alternatively, the data storage patterns DSP may include a magnetic tunnel junction pattern. In this case, the semiconductor memory device may be a magnetic random access memory (MRAM). Alternatively, the data storage patterns DSP may include a phase change material or variable resistance material. In this case, the semiconductor memory device may be a phase-change random access memory (PRAM) or resistive RAM (ReRAM).

The memory cell structure of FIGS. 4A and 4B is arranged in the memory region ME of the cell array region CA as illustrated in FIG. 2A. However, the word line WL, the bit line BL, the storage node contacts BC, the data storage pattern DSP, etc. may be arranged also in the dummy region DM in the same structure as in FIGS. 4A and 4B. Here, the word line WL, the bit line BL, the storage node contacts BC, the data storage pattern DSP, etc. arranged in the dummy region DM may be dummy patterns for preventing a loading effect and does not actually operate as a memory cell.

The embodiments of FIGS. 1 to 4B may be combined with each other.

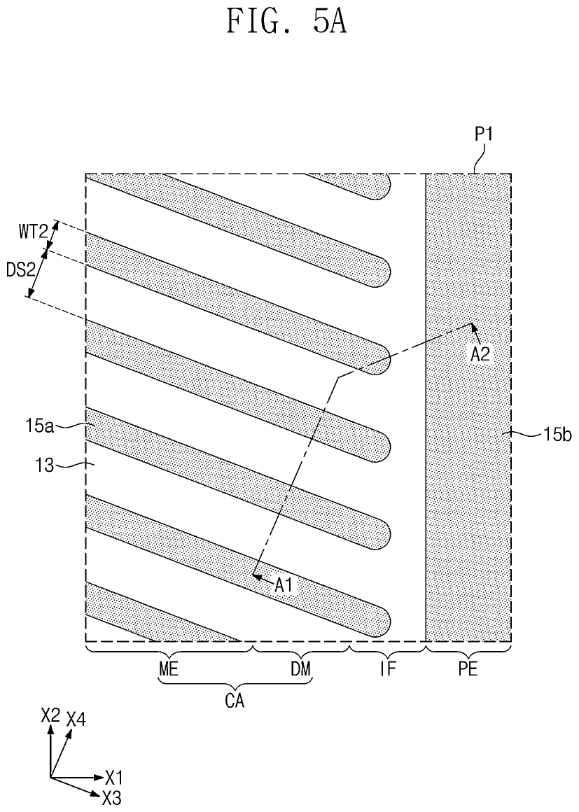

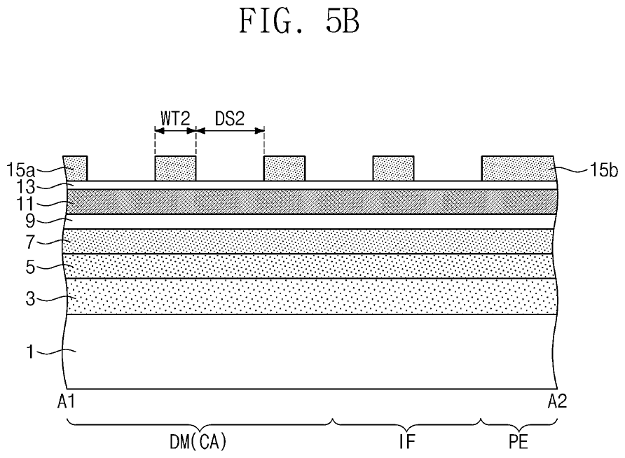

FIGS. 5A to 21A are plan views sequentially illustrating an example process of fabricating a semiconductor memory device having the plane of FIG. 2A. FIGS. 5B to 21B are cross-sectional views sequentially illustrating a process of fabricating a semiconductor memory device having the cross-section of FIG. 3.

Referring to FIGS. 5A and 5B, a first mask layer 3, a second mask layer 5, a third mask layer 7, a fourth mask layer 9, a fifth mask layer 11, and a sixth mask layer 13 are sequentially stacked on the substrate 1. The substrate 1 includes the cell array region CA, the boundary region IF, and the peripheral region PE that are arranged side by side in the first direction X1. The cell array region CA may include the memory region ME and the dummy region DM. The substrate 1 may include a semiconductor material. The substrate 1 may also be referred to as an etching target layer. In the present example, six mask layers 3, 5, 7, 9, 11, and 13 are stacked on the substrate 1, but the number of the mask layers may be five or less or seven or more.

The first mask layer 3, the second mask layer 5, the third mask layer 7, the fourth mask layer 9, the fifth mask layer 11, and the sixth mask layer 13 may be formed of materials having etching selectivity for adjacent layers. For example, the first mask layer 3 may be formed of silicon oxide. The second mask layer 5 may be formed of a silicon layer or SiGe layer. The third mask layer 7 may be formed of an amorphous carbon layer (ACL). The fourth mask layer 9 may be formed of SiCN. The fifth mask layer 11 may be formed of spin-on-hardmask (SOH). The sixth mask layer 13 may be formed of a SiON layer.

First photoresist line patterns 15a and a first photoresist peripheral pattern 15b are formed on the sixth mask layer 13. The first photoresist line patterns 15a and the first photoresist peripheral pattern 15b may be formed of photoresist through a photolithography process. The photolithography process may be performed through an I-ArF exposure process or EUV exposure process.

The first photoresist line patterns 15a may traverse the cell array region CA in the third direction X3. Ends of the first photoresist line patterns 15a may be located in the boundary region IF. The ends of the first photoresist line patterns 15a may be rounded in a plan view. The first photoresist peripheral pattern 15b may cover the peripheral region PE. The first photoresist line patterns 15a may be spaced apart from the first photoresist peripheral pattern 15b in the boundary region IF. The first photoresist line patterns 15a may be spaced a second distance DS2 apart from each other in the fourth direction X4 perpendicular to the third direction X3. The first photoresist line patterns 15a may each have a second width WT2 in the fourth direction X4. The second width WT2 versus the second distance DS2 may be about 3:5. For example, the ratio of the second width WT2 to the second distance DS2 may be about 3:5. The second width WT2 may be about three times the first width WT1 of FIG. 2A. The second distance DS2 may be about five times the first width WT1 of FIG. 2A.

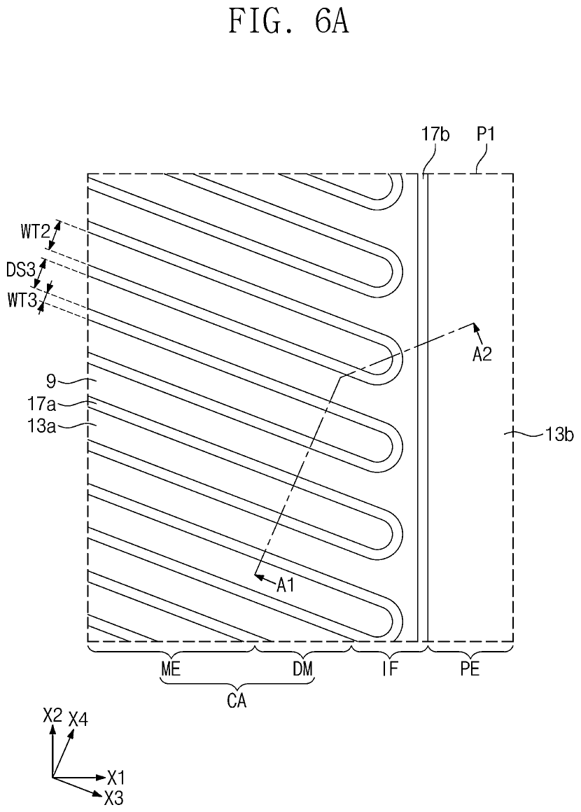

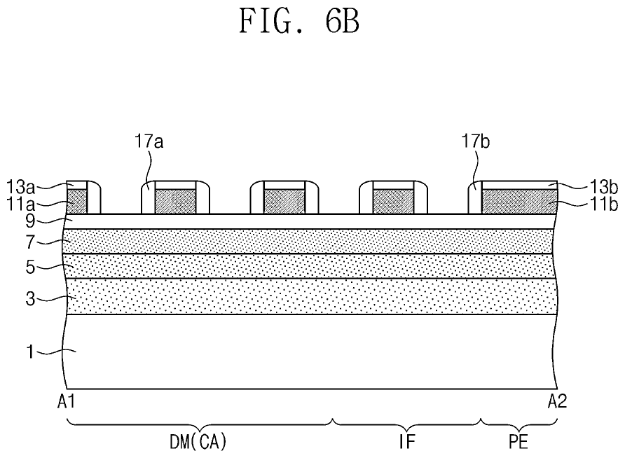

Referring to FIGS. 5A, 5B, 6A, and 6B, an upper surface of the fourth mask layer 9 is exposed and sixth mask patterns 13a and 13b and fifth mask patterns 11a and 11b are simultaneously formed by sequentially etching the sixth mask layer 13 and the fifth mask layer 11 using the first photoresist line patterns 15a and the first photoresist peripheral pattern 15b as an etching mask. The sixth mask patterns 13a and 13b include sixth line patterns 13a and a sixth peripheral pattern 13b. The fifth mask patterns 11a and 11b include fifth line patterns 11a and a fifth peripheral pattern 11b. Shapes of the first photoresist line patterns 15a may be transferred so that the sixth line patterns 13a and the fifth line patterns 11a may have the same planar shape as the first photoresist line patterns 15a. Likewise, a shape of the first photoresist peripheral pattern 15b may be transferred so that the sixth peripheral pattern 13b and the fifth peripheral pattern 11b may have the same planar shape as the first photoresist peripheral pattern 15b. The sixth line patterns 13a and the fifth line patterns 11a each may be formed to have the second width WT2 that is the same as the width of the first photoresist line patterns 15a in the fourth direction X4.

While the sixth mask layer 13 and the fifth mask layer 11 are being etched, the first photoresist line patterns 15a and the first photoresist peripheral pattern 15b may also be etched and removed. Alternatively, when the first photoresist line patterns 15a and the first photoresist peripheral pattern 15b partially remain, the first photoresist line patterns 15a and the first photoresist peripheral pattern 15b may be removed by performing an ashing process.

Referring to FIGS. 6A and 6B, first spacer patterns 17a and 17b covering sidewalls of the sixth mask patterns 13a and 13b and the fifth mask patterns 11a and 11b are formed. The first spacer patterns 17a and 17b may be formed of, for example, silicon oxide. The first spacer patterns 17a and 17b may be each formed to have a third width WT3 in the fourth direction X4. The third width WT3 may be the same as the first width WT1 of FIG. 2A.

The first spacer patterns 17a and 17b may include first cell spacer patterns 17a covering sidewalls of the sixth line patterns 13a and the fifth line patterns 11a and a first peripheral spacer pattern 17b covering sidewalls of the sixth peripheral pattern 13b and the fifth peripheral pattern 11b. A third distance DS3 between the first cell spacer patterns 17a may be the same as the second width WT2.

Forming the first spacer patterns 17a and 17b may include performing an anisotropic etching process after conformally forming a first spacer layer (not shown) on the fourth mask layer 9 in a state in which the sixth mask patterns 13a and 13b and the fifth mask patterns 11a and 11b are formed. In a plan view, the first cell spacer patterns 17a may have a closed curve shape covering ends of the sixth line patterns 13a and the fifth line patterns 11a.

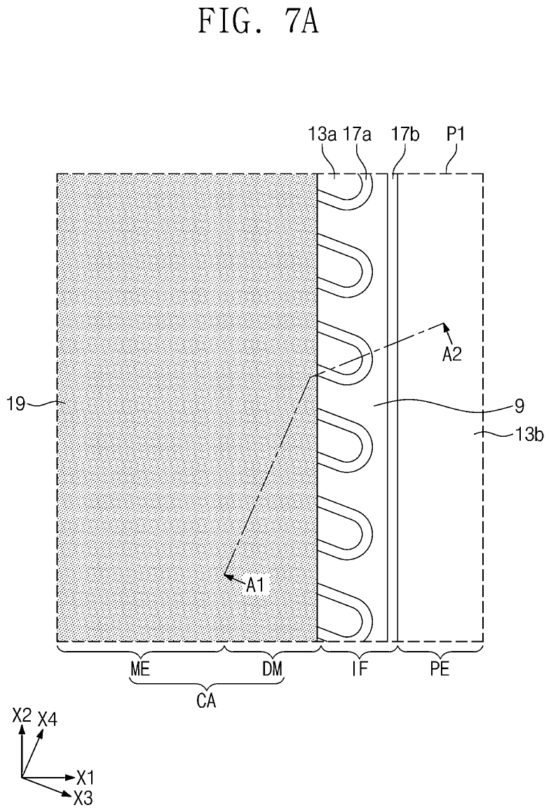

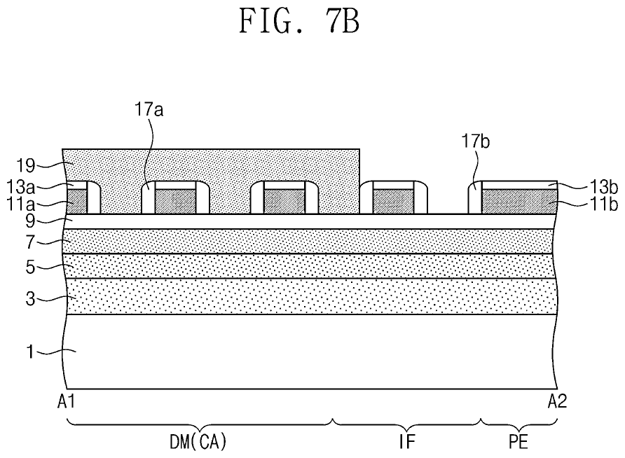

Referring to FIGS. 6A, 6B, 7A, and 7B, a second photoresist pattern 19 is formed, which covers the fourth mask layer 9, the sixth line patterns 13a, and the first cell spacer patterns 17a in the cell array region CA of the substrate 1 and exposes the boundary region IF and the peripheral region PE. The second photoresist pattern 19 may expose the fourth mask layer 9, the sixth line patterns 13a, and the first cell spacer patterns 17a in the boundary region IF and expose the sixth peripheral pattern 13b and the first peripheral spacer pattern 17b in the peripheral region PE.

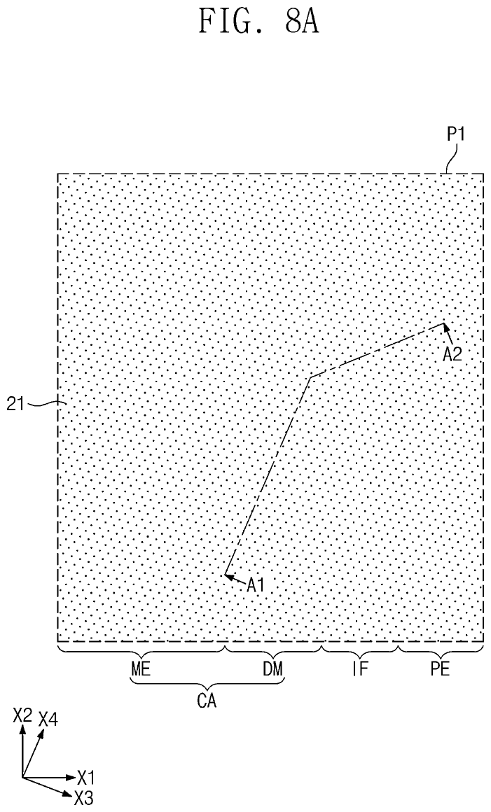

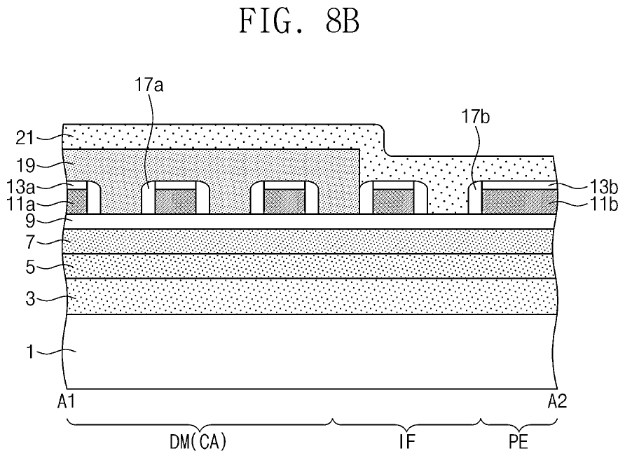

Referring to FIGS. 8A and 8B, a buried layer 21 is stacked on the second photoresist pattern 19 and the fourth mask layer 9. The buried layer 21 may be formed of, for example, silicon oxide. The buried layer 21 may be formed through a deposition process such as atomic layer deposition (ALD). The buried layer 21 may fill a space between the first cell spacer patterns 17a and the first peripheral spacer pattern 17b in the boundary region IF.

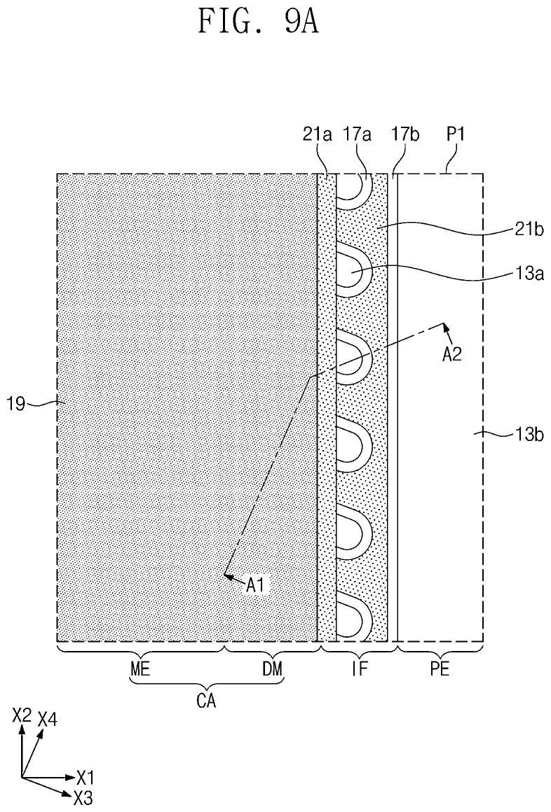

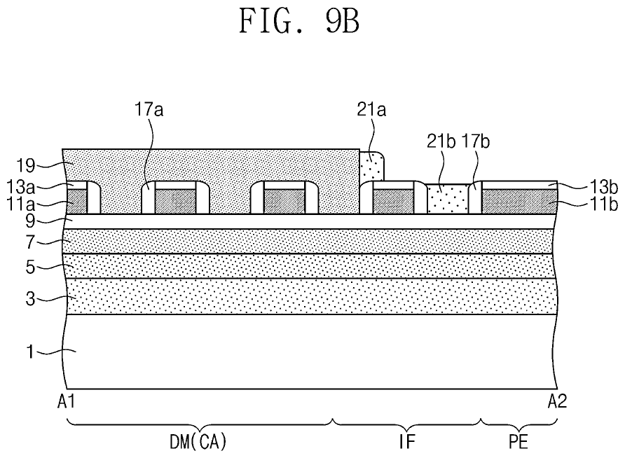

Referring to FIGS. 9A and 9B, an anisotropic etching process is performed on the buried layer 21 so as to remove the buried layer 21 on the second photoresist pattern 19 and leave a buried pattern 21b between the first cell spacer patterns 17a and the first peripheral spacer pattern 17b. Here, a residual buried pattern 21a covering a sidewall of the second photoresist pattern 19 may be formed. The buried pattern 21b and the residual buried pattern 21a may be formed of silicon oxide.

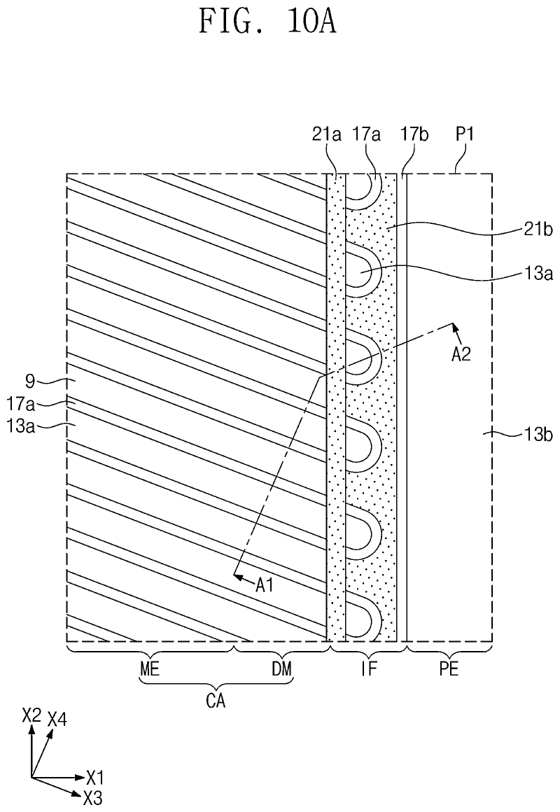

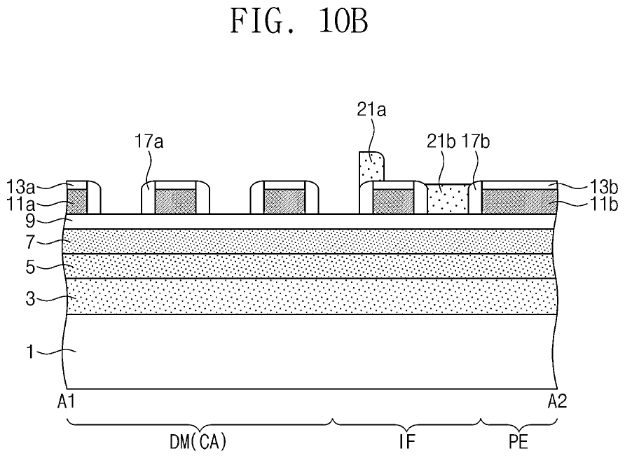

Referring to FIGS. 10A and 10B, the fourth mask layer 9, the sixth line patterns 13a, and the first cell spacer patterns 17a in the cell array region CA are exposed by removing the second photoresist pattern 19. The second photoresist pattern 19 may be removed through an ashing process.

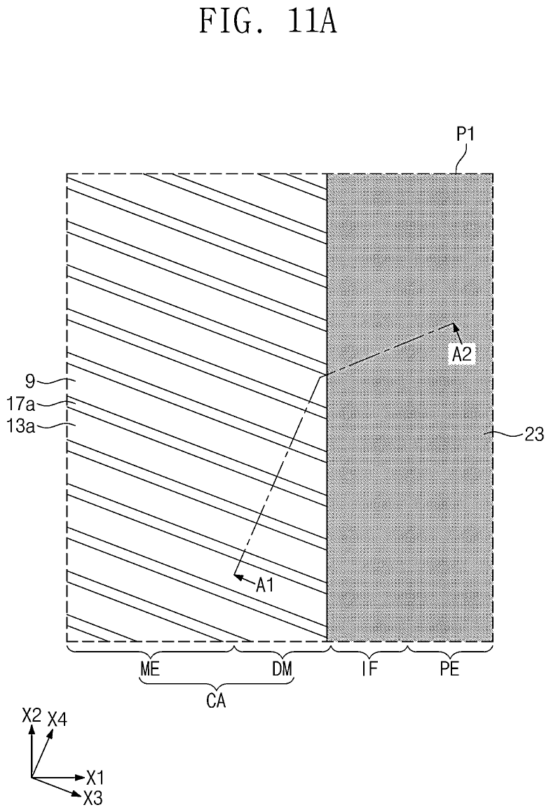

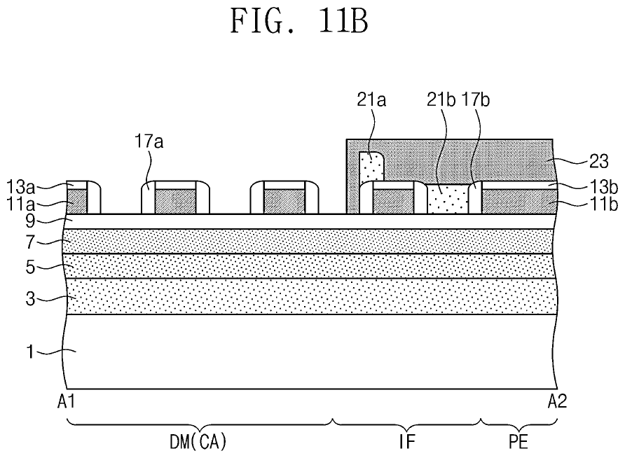

Referring to FIGS. 11A and 11B, a third photoresist pattern 23 is formed, which covers the fourth mask layer 9, ends of the sixth line patterns 13a, ends of the first cell spacer patterns 17a, the sixth peripheral pattern 13b, the first peripheral spacer pattern 17b, the buried pattern 21b, and the residual buried pattern 21a in the boundary region IF and the peripheral region PE, and exposes the fourth mask layer 9, the sixth line patterns 13a, and the first cell spacer patterns 17a in the cell array region CA. The third photoresist pattern 23 may cover both sidewalls of the residual buried pattern 21a.

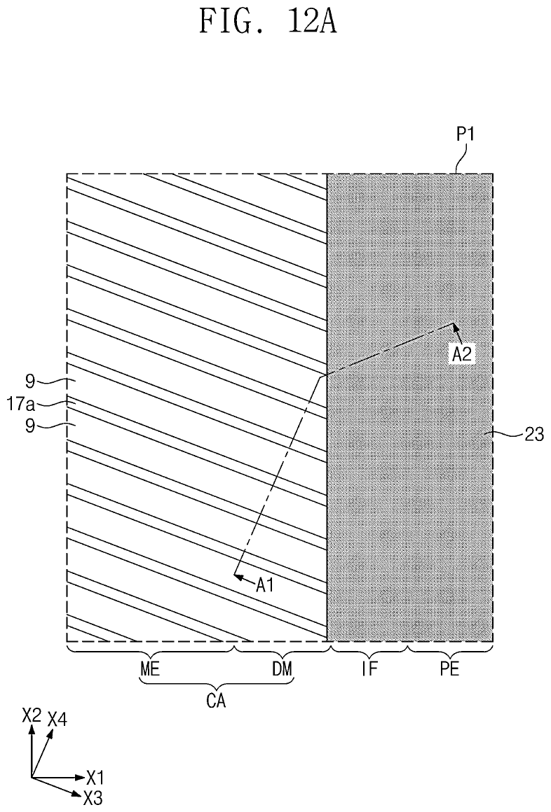

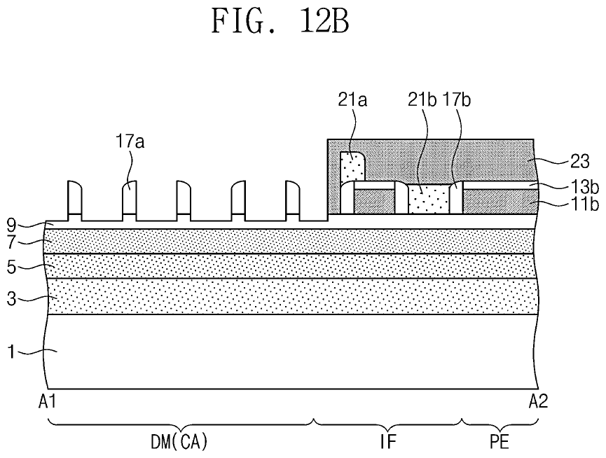

Referring to FIGS. 11A, 11B, 12A, and 12B, an upper surface of the fourth mask layer 9 is exposed by removing the sixth line patterns 13a and the fifth line patterns 11a in the cell array region CA. Here, an upper portion of the fourth mask layer 9 may be partially removed in the cell array region CA. Here, the boundary region IF and the peripheral region PE may be protected by the third photoresist pattern 23.

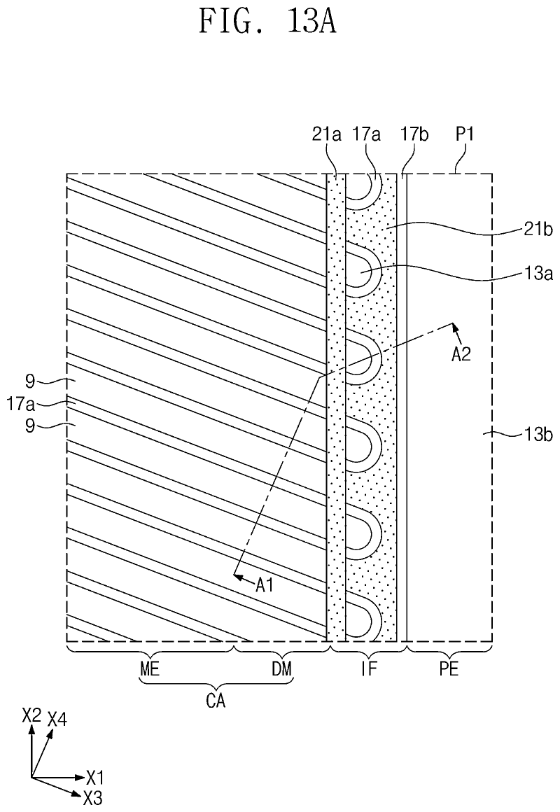

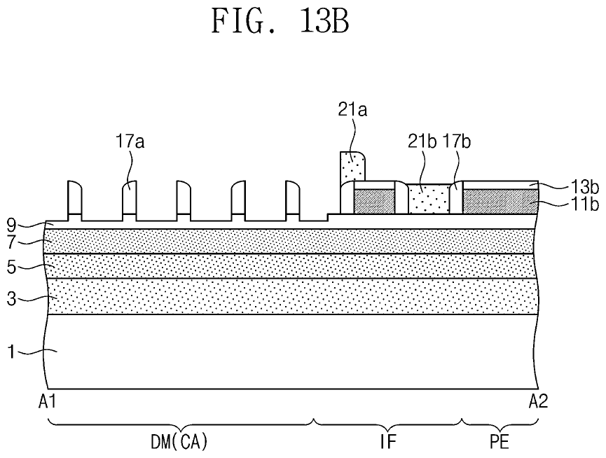

Referring to FIGS. 12A, 12B, 13A, and 13B, the fourth mask layer 9, the sixth line patterns 13a, the first cell spacer patterns 17a, the sixth peripheral pattern 13b, the first peripheral spacer pattern 17b, the buried pattern 21b, and the residual buried pattern 21a in the boundary region IF and the peripheral region PE are exposed by removing the third photoresist pattern 23. The third photoresist pattern 23 may be removed through an ashing process. Ends of the sixth line patterns 13a, ends of the first cell spacer patterns 17a, the sixth peripheral pattern 13b, the first peripheral spacer pattern 17b, the buried pattern 21b, and the residual buried pattern 21a may be in contact with each other in the boundary region IF and the peripheral region PE.

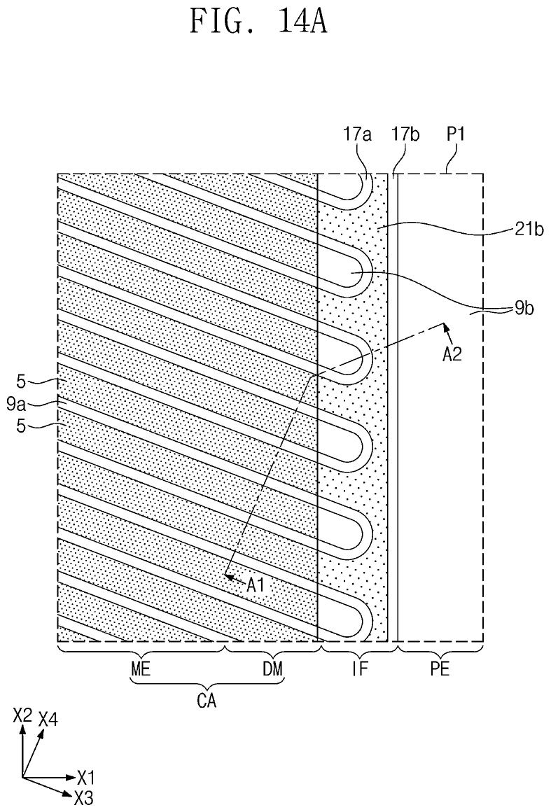

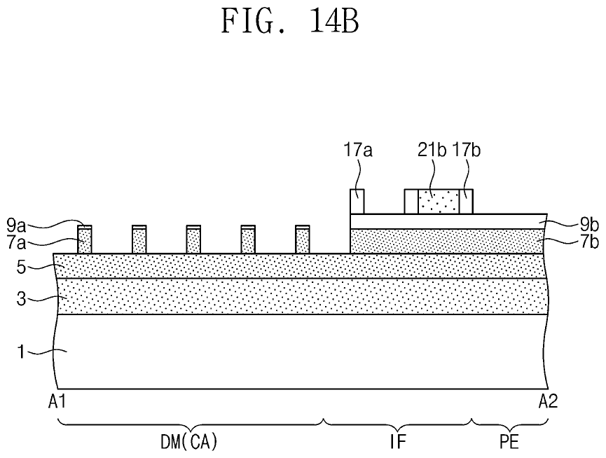

Referring to FIGS. 13A, 13B, 14A, and 14B, fourth line patterns 9a and third line patterns 7a are formed by sequentially etching the fourth mask layer 9 and the third mask layer 7 using the first cell spacer patterns 17a as an etching mask in the cell array region CA. While the fourth line patterns 9a and the third line patterns 7a are being formed, the first cell spacer patterns 17a may also be etched and removed.

When forming the fourth line patterns 9a and the third line patterns 7a in the cell array region CA, a fourth peripheral pattern 9b and a third peripheral pattern 7b are formed by sequentially etching the fourth mask layer 9 and the third mask layer 7 using ends of the sixth line patterns 13a, ends of the first cell spacer patterns 17a, the sixth peripheral pattern 13b, the first peripheral spacer pattern 17b, the buried pattern 21b, and the residual buried pattern 21a as an etching mask in the boundary region IF and the peripheral region PE. In FIG. 13B, since ends of the sixth line patterns 13a, ends of the first cell spacer patterns 17a, the sixth peripheral pattern 13b, the first peripheral spacer pattern 17b, the buried pattern 21b, and the residual buried pattern 21a are in contact with each other, thus forming a single agglomeration (or assemblage) and functioning as an etching mask of a bulk pattern type in the boundary region IF and the peripheral region PE, the fourth peripheral pattern 9b and the third peripheral pattern 7b are each formed to have a wider width than the sixth peripheral pattern 13b and cover not only the peripheral region PE but also the boundary region IF.

While the mask layer 9 and the third mask layer 7 are being etched in the boundary region IF and the peripheral region PE, the sixth line patterns 13a, the fifth line patterns 11a, the sixth peripheral pattern 13b, the fifth peripheral pattern 11b, and the residual buried pattern 21a of FIG. 13B that are located on the mask layer 9 and the third mask layer 7 may also be etched and removed, and ends of the first cell spacer patterns 17a, the first peripheral spacer pattern 17b, and the buried pattern 21b may remain on the fourth peripheral pattern 9b.

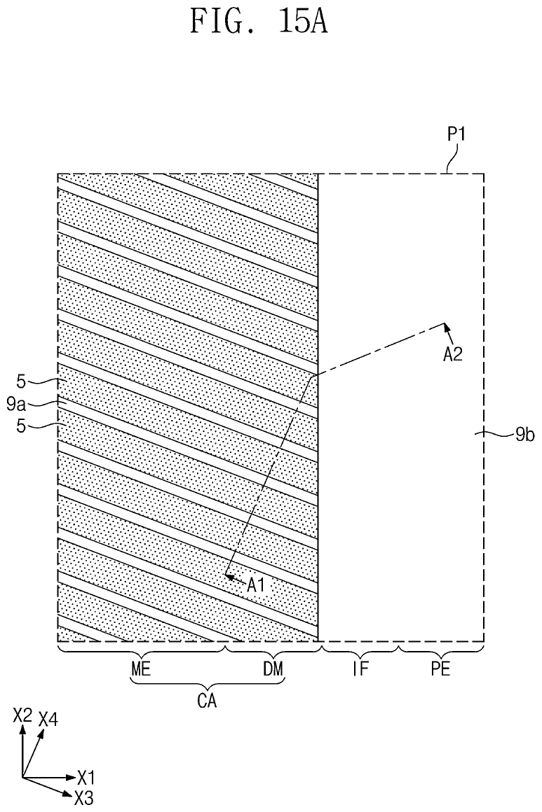

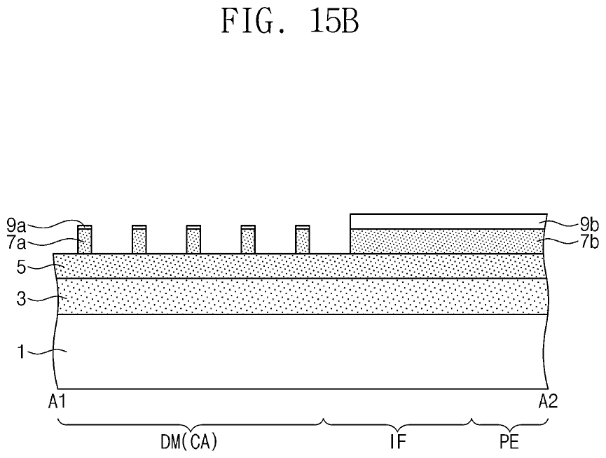

Referring to FIGS. 14A, 14B, 15A, and 15B, ends of the first cell spacer patterns 17a, the first peripheral spacer pattern 17b, and the buried pattern 21b on the fourth peripheral pattern 9b are removed, and an upper surface of the fourth peripheral pattern 9b is exposed. Ends of the first cell spacer patterns 17a, the first peripheral spacer pattern 17b, and the buried pattern 21b may be all formed of silicon oxide, and may be removed using, for example, a hydrofluoric acid (HF). Here, damage to the fourth line patterns 9a and the third line patterns 7a is minimized by appropriately adjusting a processing time with the hydrofluoric acid. In the plan view of FIG. 15A, ends of the fourth line patterns 9a may be in contact with the fourth peripheral pattern 9b. The fourth line patterns 9a may be formed to have a smaller thickness than the fourth peripheral pattern 9b. Herein, the term “thickness” may refer to a thickness or height in a direction perpendicular to an upper surface of the substrate 1.

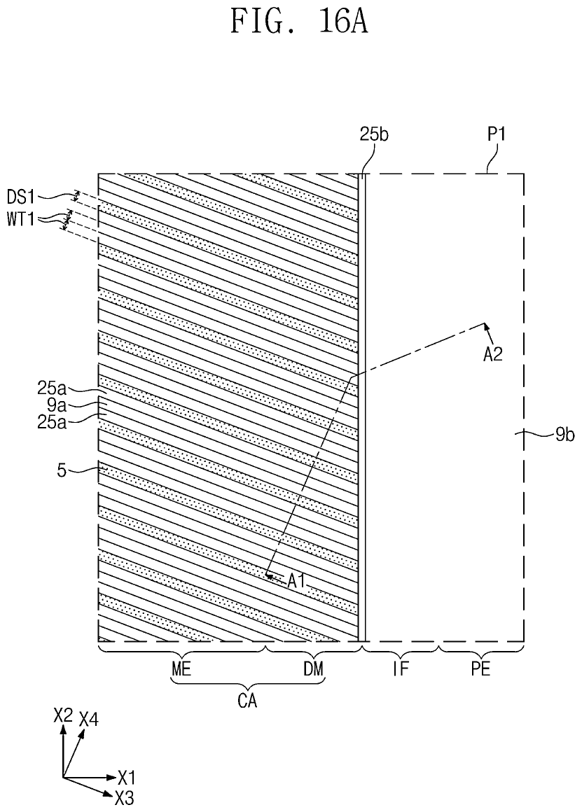

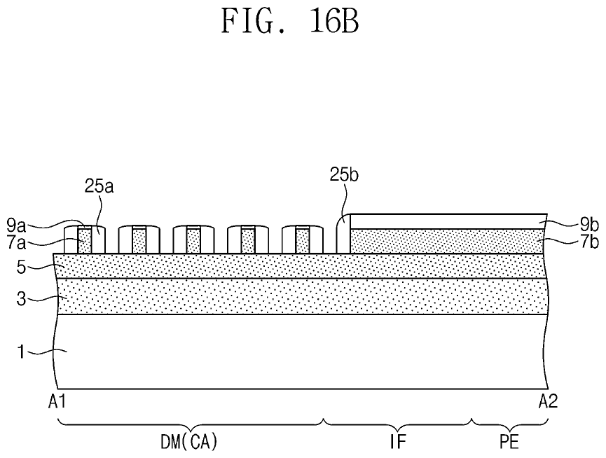

Referring to FIGS. 16A and 16B, second cell spacer patterns 25a and a second peripheral spacer pattern 25b are formed by performing an anisotropic etching process after conformally stacking a second spacer layer on the second mask layer 5. The second cell spacer patterns 25a cover sidewalls of the fourth line patterns 9a and the third line patterns 7a. The second peripheral spacer pattern 25b covers sidewalls of the fourth peripheral pattern 9b and the third peripheral pattern 7b.

The second cell spacer patterns 25a and the second peripheral spacer pattern 25b may be formed of, for example, silicon oxide. The fourth line patterns 9a, the third line patterns 7a, the second cell spacer patterns 25a, and the second peripheral spacer pattern 25b may be each formed to have the first width WT1 in the fourth direction X4. The second cell spacer patterns 25a may be spaced the first distance DS1 apart in the fourth direction X4. The first distance DS1 may be equal to the first width WT1.

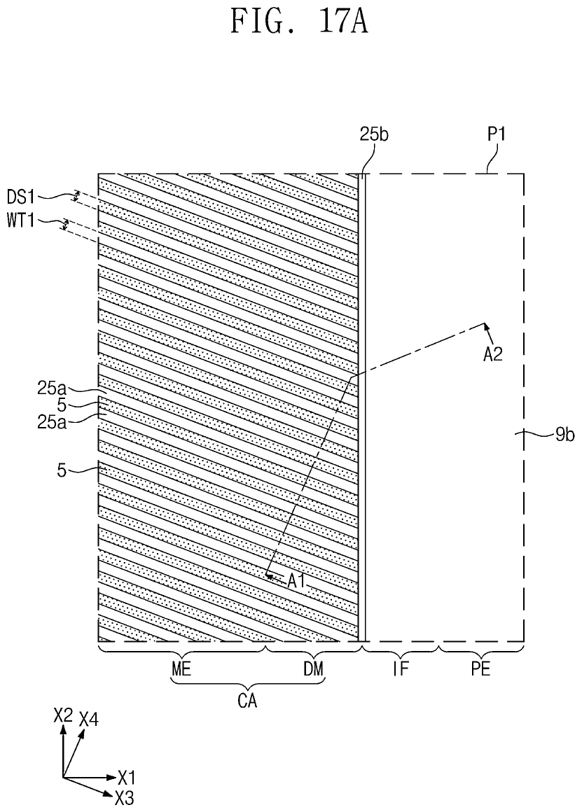

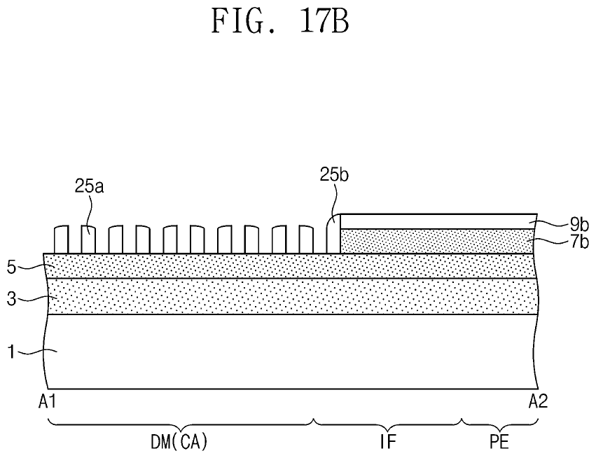

Referring to FIGS. 16A, 16B, 17A, and 17B, an upper surface of the second mask layer 5 between the second cell spacer patterns 25a is exposed by removing the fourth line patterns 9a and the third line patterns 7a in the cell array region CA. Since the fourth peripheral pattern 9b is thicker than the fourth line patterns 9a, the fourth peripheral pattern 9b may remain and protect the third peripheral pattern 7b under the fourth peripheral pattern 9b when removing the fourth line patterns 9a.

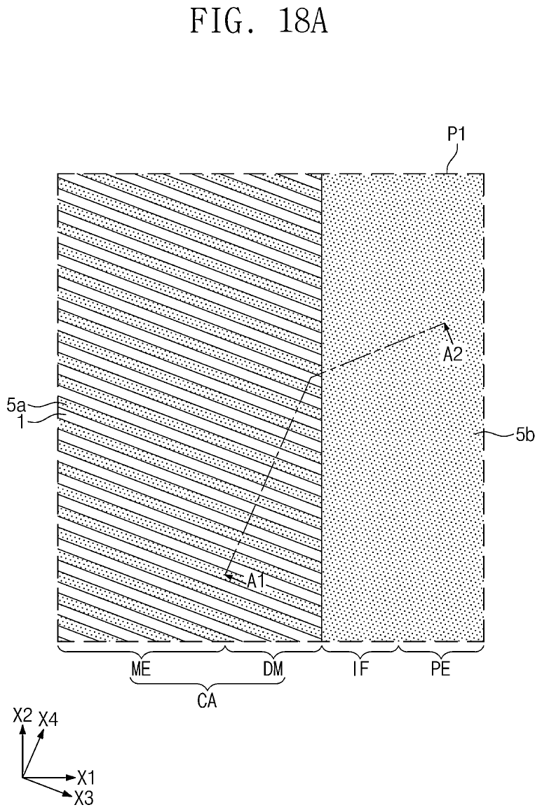

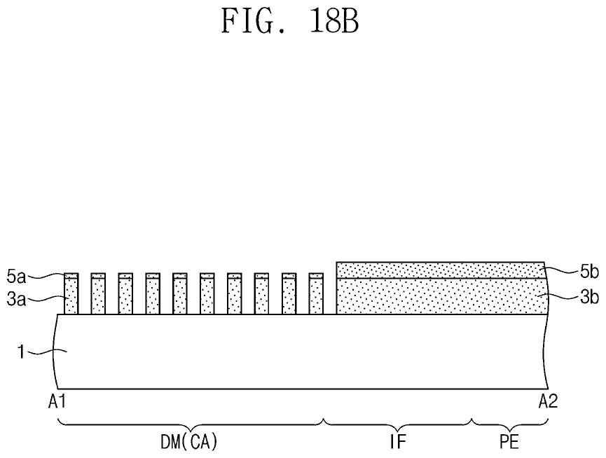

Referring to FIGS. 17A, 17B, 18A, and 18B, second line patterns 5a and first line patterns 3a may be formed and an upper surface of the substrate 1 may be exposed by sequentially etching the second mask layer 5 and the first mask layer 3 using the second cell spacer patterns 25a as an etching mask in the cell array region CA. While the second line patterns 5a and the first line patterns 3a are being formed, the second cell spacer patterns 25a may also be etched and removed.

When forming the second line patterns 5a and the first line patterns 3a in the cell array region CA, a second peripheral pattern 5b and a first peripheral pattern 3b may be formed and an upper surface of the substrate 1 may be exposed by sequentially etching the second mask layer 5 and the first mask layer 3 using the fourth peripheral pattern 9b and the third peripheral pattern 7b as an etching mask in the boundary region IF and the peripheral region PE. When forming the second peripheral pattern 5b and the first peripheral pattern 3b, the fourth peripheral pattern 9b and the third peripheral pattern 7b may be all also etched and removed. Since a planar shape of the second cell spacer patterns 25a is transferred as is to form the second line patterns 5a and the first line patterns 3a, the second line patterns 5a and the first line patterns 3a may also have the first width WT1 of FIG. 17A.

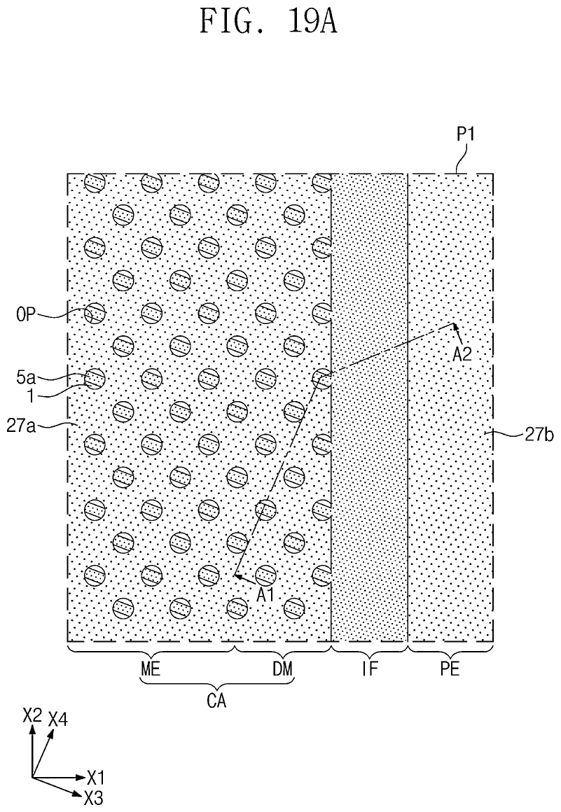

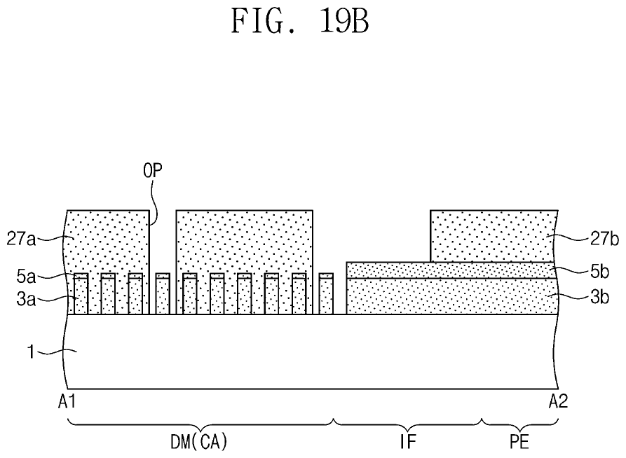

Referring to FIGS. 19A and 19B, a seventh cell mask pattern 27a covering the second line patterns 5a in the cell array region CA and a seventh peripheral mask pattern 27b covering the second peripheral pattern 5b in the peripheral region PE and the boundary region IF are formed. The seventh cell mask pattern 27a may be spaced apart from the seventh peripheral mask pattern 27b and may partially expose the second peripheral pattern 5b in the boundary region IF. The seventh cell mask pattern 27a and the seventh peripheral mask pattern 27b may be, for example, photoresist patterns.

The seventh cell mask pattern 27a may include a plurality of openings OP exposing the second line patterns 5a. The openings OP may have a circular shape in a plan view and may be two-dimensionally arranged along the first direction X1 and the second direction X2. The openings OP may be arranged in a form of honeycomb. That is, one opening OP may be arranged at a center of a virtual hexagon, and six openings OP surrounding the one opening OP may be arranged at vertices of the virtual hexagon. The openings OP may be wider than the width (first width WT1 of FIG. 17A) of the second line patterns 5a in the fourth direction X4. Some of the openings OP may be formed at an edge of the seventh cell mask pattern 27a so that a side surface of the seventh cell mask pattern 27a may have a protrusion and recess structure in a plan view. The seventh peripheral mask pattern 27b may have a line shape extending in the second direction X2 while covering the peripheral region PE. The seventh peripheral mask pattern 27b may surround the cell array region CA of FIG. 1.

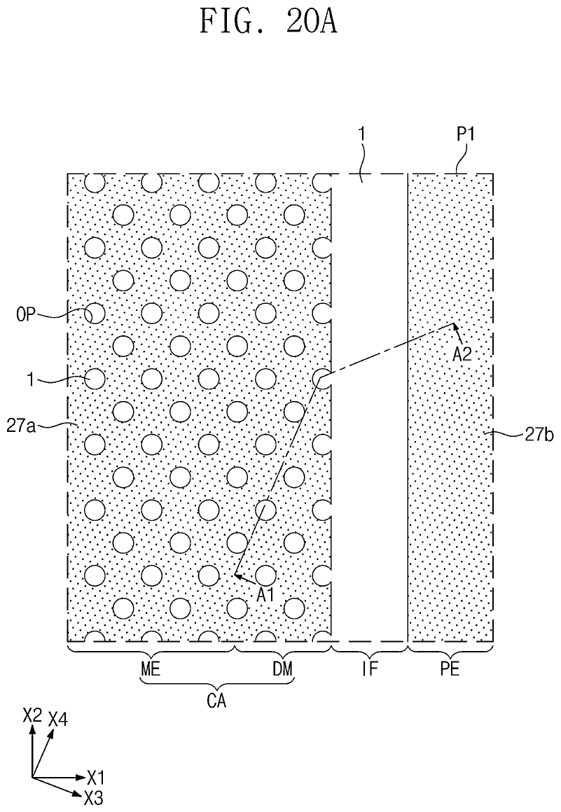

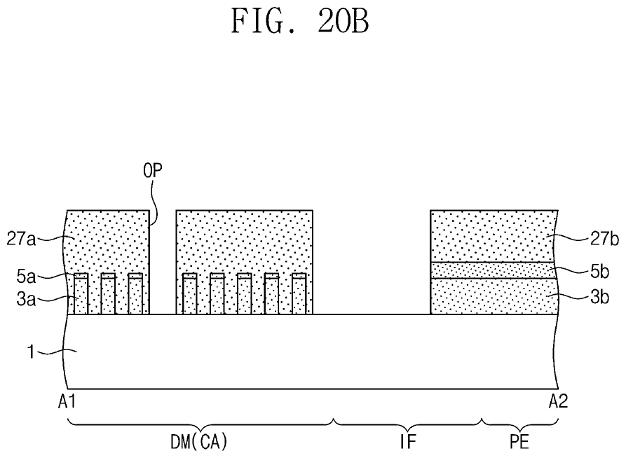

Referring to FIGS. 19A, 19B, 20A, and 20B, the second line patterns 5a and the first line patterns 3a exposed to the openings OP are removed using the seventh cell mask pattern 27a as an etching mask, and an upper surface of the substrate 1 is exposed through the openings OP. Accordingly, the first line patterns 3a may be disconnected in the third direction X3 and may have a bar shape elongated in the third direction X3 in a plan view like the active parts AC of FIG. 2A. Here, an upper surface of the substrate 1 is exposed by partially removing the second peripheral pattern 5b and the first peripheral pattern 3b in the boundary region IF using the seventh peripheral mask pattern 27b as an etching mask.

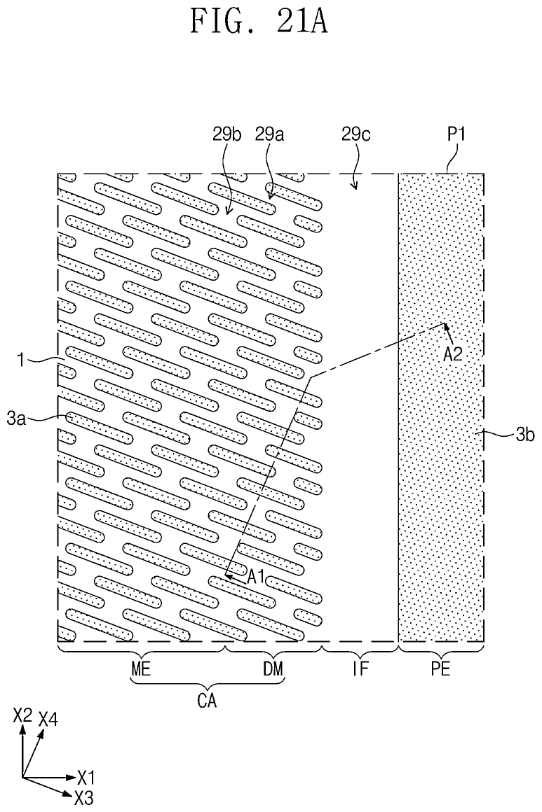

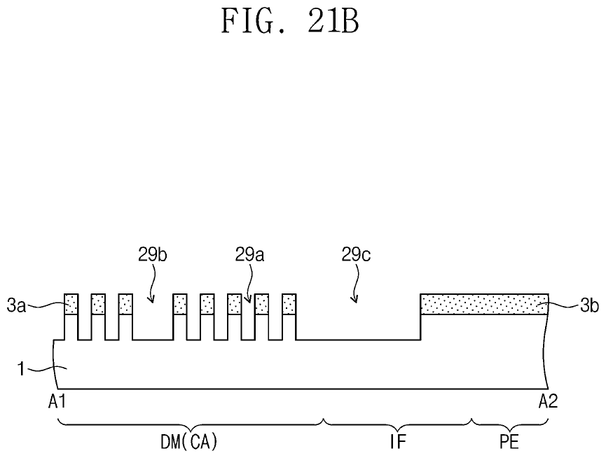

Referring to FIGS. 20A, 20B, 21A, and 21B, the seventh cell mask pattern 27a and the seventh peripheral mask pattern 27b are removed. Furthermore, first trenches 29a and second trenches 29b are formed by etching the substrate 1 using the second line patterns 5a and the first line patterns 3a as an etching mask in the cell array region CA, and the substrate 1 is etched using the second peripheral pattern 5b and the first peripheral pattern 3b as an etching mask in the peripheral region PE and the boundary region IF. Accordingly, a third trench 29c is formed in the boundary region IF. The first trenches 29a may have a wider width than the second trenches 29b in the fourth direction X4. The third trench 29c may have a wider width than the first trenches 29a and the second trenches 29b. The first trenches 29a, the second trenches 29b, and the third trench 29c are connected to each other. Protrusions of the substrate 1 defined by the first trenches 29a, the second trenches 29b, and the third trench 29c may become the active parts AC of FIG. 2A. While etching the substrate 1, the second line patterns 5a and the second peripheral pattern 5b may be all etched and removed and only the first line patterns 3a and the first peripheral pattern 3b may remain.

Thereafter, referring to FIGS. 21A, 21B, 2A, and 2B, the device isolation part 31 may be formed in the first trenches 29a, the second trenches 29b, and the third trench 29c by performing a chemical mechanical polishing (CMP) process or etch-back process after stacking a device isolation layer on a front surface of the substrate 1, the first line patterns 3a and the first peripheral pattern 3b may be removed, and an upper surface of the substrate 1 may be exposed. Accordingly, the semiconductor memory device of FIGS. 2A and 2B may be fabricated.

The semiconductor memory device of FIG. 2B or 2C may be fabricated by changing arrangement of the openings OP at an edge of the seventh cell mask pattern 27a of FIG. 19A.

In a photolithography process, it becomes more difficult to accurately form ends of the first photoresist line patterns 15a of FIG. 5A at an edge of the cell array region CA due to interference of light or the like as the line width of a pattern decreases, and thus a process fault such as an end pattern fault may occur. Such a process fault may more frequently occur when an I-ArF (Immersion-ArF) exposure process is used.

In an embodiment of the inventive concept, the first photoresist line patterns 15a are formed to be long in the third direction X3 as illustrated in FIG. 5A so that ends of the first photoresist line patterns 15a are arranged up to the boundary region IF outside the cell array region CA. Furthermore, as illustrated in FIGS. 9A and 9B, the buried pattern 21b fills a space between the sixth and fifth peripheral patterns 13b and 11b and ends of the sixth and fifth line patterns 13a and 11a which are formed using the first photoresist line patterns 15a and to which an end pattern fault of the first photoresist line patterns 15a may be transferred. Therefore, a pattern fault of ends of the sixth and fifth line patterns 13a and 11a is not transferred to ends of the first to fourth line patterns 3a, 5a, 7a, and 9a. That is, a faulty pattern is not formed in the boundary region IF. Accordingly, a semiconductor memory device with improved reliability may be fabricated. Furthermore, the yield may be improved by resolving a process fault. Moreover, a method of fabricating a semiconductor memory device according to an embodiment of the inventive concept may use I-ArF exposure equipment without requiring extreme ultraviolet (EUV) exposure equipment that increases a process cost, and thus may reduce the process cost.

Since no faulty pattern remains in the boundary region in the semiconductor memory device according to an embodiment of the inventive concept, the reliability of the device may be improved. Furthermore, ends of the active parts are arranged on the imaginary straight line at an edge of the cell array region and do not protrude to the boundary region. Therefore, the degree of integration of the semiconductor memory device may be increased, and the reliability may be improved.

In a method of fabricating a semiconductor memory device according to an embodiment of the inventive concept, a space between a peripheral pattern and ends of line patterns where a pattern fault may occur is filled with a buried pattern, and thus a fault of the ends of the line patterns is not transferred to layers under the line patterns. Accordingly, a process fault may be prevented, and the yield may be improved.

Although the embodiments of the present invention have been described, it is understood that the present invention should not be limited to these embodiments but various changes and modifications can be made by one ordinary skilled in the art within the spirit and scope of the present invention as hereinafter claimed.

1. A semiconductor memory device comprising:
a substrate including a memory region, a dummy region, and a peripheral region arranged side by side in a first direction; and
a device isolation part arranged in the substrate in the memory region and the dummy region and defining active parts,
wherein the active parts include first to third active parts arranged side by side in a second direction perpendicular to the first direction in the dummy region,
wherein the first to third active parts are each elongated in a third direction intersecting the first direction and the second direction, and
wherein ends of at least two of the first to third active parts are located on a first imaginary straight line extending in the second direction.

2. The semiconductor memory device of claim 1,
wherein only ends of the second and third active parts are located on the first imaginary straight line, and
wherein an end of the first active part is spaced apart from the first imaginary straight line.

3. The semiconductor memory device of claim 1,
wherein the first active part has a first length in the third direction,
wherein the second active part has a second length different from the first length in the third direction, and
wherein the third active part has a third length different from both the first length and the second length in the third direction.

4. The semiconductor memory device of claim 1,
wherein the active parts include fourth active parts arranged in the memory region and elongated in the third direction, and
wherein the semiconductor memory device further comprises:
word lines arranged in the substrate and traversing the fourth active parts in the second direction; and
bit lines arranged on the substrate and traversing the fourth active parts in the first direction.

5. The semiconductor memory device of claim 1,
wherein the substrate further includes a boundary region arranged between the dummy region and the peripheral region, and
wherein the device isolation part extends to be arranged in the boundary region and defines the peripheral region.

6. The semiconductor memory device of claim 1,
wherein the first to third active parts are spaced apart from each other by a first distance in a fourth direction intersecting the first and second directions and perpendicular to the third direction,
wherein each of the first to third active parts has a first width in the fourth direction, and
wherein the first width is equal to the first distance.

7. The semiconductor memory device of claim 1,
wherein the first to third active parts form a single group, and
wherein the single group is provided in plurality and repeatedly arranged in the second direction.

8. A semiconductor memory device comprising:
a substrate including a memory region, a dummy region, and a peripheral region arranged side by side in a first direction; and
a device isolation part arranged in the substrate in the memory region and the dummy region and defining active parts,
wherein the active parts include first to third active parts arranged in the dummy region and fourth active parts arranged in the memory region,
wherein the first to third active parts are arranged side by side in a second direction perpendicular to the first direction,
wherein the first to fourth active parts are elongated in a third direction intersecting the first direction and the second direction,
wherein one of the first to third active parts has a first length in the third direction, and
wherein each of the fourth active parts has a second length smaller than the first length in the third direction.

9. The semiconductor memory device of claim 8, wherein ends of the first to third active parts are located on a first imaginary straight line extending in the second direction.

10. The semiconductor memory device of claim 8,
wherein the one of the first to third active parts is the first active part,
wherein the second active part has a third length smaller than the second length in the third direction, and
wherein the third active part has a fourth length smaller than the first length and larger than the third length in the third direction.

11. The semiconductor memory device of claim 8, further comprising:
word lines arranged in the substrate, extending lengthwise in the second direction, and traversing the fourth active parts; and
bit lines arranged on the substrate, extending lengthwise in the first direction, and traversing the fourth active parts.

12. The semiconductor memory device of claim 8,
wherein the substrate further includes a boundary region arranged between the dummy region and the peripheral region, and
wherein the device isolation part extends to the boundary region and defines the peripheral region.

13. The semiconductor memory device of claim 8,
wherein the first to third active parts are spaced apart from each other by a first distance in a fourth direction intersecting the first and second directions and perpendicular to the third direction,
wherein the first to third active parts each have a first width in the fourth direction, and
wherein the first width is equal to the first distance.

14. A semiconductor memory device comprising:
a substrate including a cell array region and a peripheral region arranged side by side in a first direction;
a device isolation part arranged in the substrate in the cell array region and defining active parts, wherein the active parts are arranged two-dimensionally in the first direction and a second direction perpendicular to the first direction, and each of the active parts is elongated in a third direction intersecting the first direction and the second direction;
word lines arranged in the substrate, extending lengthwise in the second direction, and traversing the active parts in the cell array region;
first impurity regions arranged in the active parts and adjacent to first sidewalls of the word lines;
second impurity regions arranged in the active parts and adjacent to second sidewalls of the word lines;
bit lines respectively connected to the first impurity regions, arranged on the substrate, and extending in the first direction; and
storage node contacts respectively connected to the second impurity regions,
wherein ends of at least two among the active parts that are closest to the peripheral region are located on a first imaginary straight line extending in the second direction.

15. The semiconductor memory device of claim 14,
wherein the active parts are spaced apart from each other by a first distance in a fourth direction intersecting the first and second directions and perpendicular to the third direction,
wherein the active parts each have a first width in the fourth direction, and
wherein the first width is equal to the first distance.

16. The semiconductor memory device of claim 14,
wherein the active parts that are closest to the peripheral region among the active parts include first to third active parts arranged side by side in the second direction,
wherein ends of the second and third active parts are located on the first imaginary straight line, and
wherein an end of the first active part is spaced apart from the first imaginary straight line.

17. The semiconductor memory device of claim 16,
wherein the first active part has a first length in the third direction,
wherein the second active part has a second length smaller than the first length in the third direction, and
wherein the third active part has a third length larger than the second length and smaller than the first length in the third direction.

18. The semiconductor memory device of claim 17,
wherein the first to third active parts form a single group, and
wherein the single group is provided in plurality and repeatedly arranged in the second direction.

19. The semiconductor memory device of claim 17,
wherein the cell array region includes a memory region and a dummy region,
wherein the dummy region is arranged between the memory region and the peripheral region,
wherein the first to third active parts are arranged in the dummy region,
wherein the active parts further include fourth active parts arranged in the memory region, and
wherein each of the fourth active parts has a fourth length larger than the second length and smaller than the first length in the third direction.

20. The semiconductor memory device of claim 14,
wherein the substrate further includes a boundary region arranged between the cell array region and the peripheral region, and
wherein the device isolation part extends to be arranged in the boundary region and defines the peripheral region.

21-29. (canceled)
